(19) United States
(12) Patent Application Publication
(10) Pub. No.: US 2002/0061471 A1
(43) Pub. Date: May 23, 2002

(54) Pattern forming method

(75) Inventor: Masashi Fujimoto, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/987,928

(22) Filed: Nov. 16, 2001

(30) Foreign Application Priority Data
Nov. 17, 2000 (JP) 2000-351164

(51) Int. Cl. G03F 9/00; G03C 5/00; H01J 37/08; G21K 5/10

(52) U.S. Cl. 430/322; 430/5; 430/311; 250/492.22; 250/492.23

(57) ABSTRACT

As a phase-shift mask 10, a positive type Levenson phase-shift mask is used. For example, a device having such a minimum line-width of about 100 nm as that of a gate layer circuit pattern 14 is exposed by a projection exposure apparatus using a KrF-Excimer laser as its light source. The circuit pattern 14 is formed by performing exposure twice using the phase-shift mask 10 and an ordinary mask 12 respectively. In this case, during the first time of exposure by use of the phase-shift mask 10, a substrate 141 is moved along an optical axis to expose the pattern onto a plurality of image-forming surfaces. By this multiple-focus exposure method, the errors in pattern dimensions can be averaged into a small value.

### BACKGROUND OF THE INVENTION

1. Field of the Invention

The present invention relates to a pattern forming method used in a fine patterning technology for manufacturing semiconductor devices by which method a predetermined pattern is formed on a resist film on a substrate through exposure using a phase-shift mask. Hereinafter, exposure using the phase-shift mask is abbreviated as “phase-shift exposure”.

2. Description of the Related Art

Recently, with the ever increasing speed and integration density of semiconductor devices, their pattern dimensions have been more and more required to be finer. As a result, the design rule has been reduced to a half of a wavelength of an exposure light.

For example, FIG. 8 is a graph for showing an optical contrast of isolated 100-nm-wide lines for KrF-Excimer laser exposure (wavelength: 248 nm) and ArF-Excimer laser exposure (wavelength: 193 nm). The optical contrast here is defined as ([light intensity at pattern center] −[light intensity at pattern edge])÷[light intensity at pattern edge], whereby the optical contrast of about at least 0.5 is considered to be necessary to resolve a pattern into an acceptable shape. As can be seen from this graph of FIG. 8, such a pattern that is of a design rule of 100 nm, which is not wider than half of the exposure light wavelength, is extremely difficult to form by an exposure technique using an ordinary mask, so that a variety of ultra-fine resolving technologies have been discussed to solve this problem. Among them, a Levenson phase-shift mask (see Japanese Patent Publication (KOKOKU) No. Sho 62-50811) has a large effect especially on improvement of the optical contrast and the resolution and is considered to be the most hopeful technology in forming a pattern of a design rule of not wider than a half of the exposure light wavelength of a light.

A prior art phase-shift exposure method, however, has a problem that a pattern dimension expands rapidly with an increasing defocus amount as shown in FIG.

Accordingly, the pattern dimensions fluctuate in response to irregularities in the surface of a wafer.

Also, as shown in FIG. 10, if a spherical aberration of the lens is remaining, gives rise to asymmetry between a plus (+) defocus and a minus (−) defocus, thus leading to a problem of a large decrease in dimensional accuracy. The phase-shift exposure method greatly utilizes phase information under high-coherence conditions and, in principle, is much sensitive to the optical parameters. It is, therefore, greatly influenced by a lens aberration, which appears in phase error when an image is formed.

### SUMMARY OF THE INVENTION

In view of the above, it is an object of the invention to provide a pattern forming-method by means of phase-shifted exposure for improving a dimensional accuracy by eliminating an influence of a defocus and a spherical aberration.

The present invention is, a pattern forming method for forming a predetermined pattern onto a resist film on a substrate by exposing said predetermined pattern through a phase-shift mask while moving at least one of said phase-shift mask and said substrate by a constant distance along an optical axis.

In present invention, it may be, for example, that a positive type Levenson phase-shift mask and a line pattern are employed, the line pattern's lower dimensional limit is not more than a wavelength of an exposure light, a coherence factor of an exposure illumination optical system is not more than 0.5, and the constant distance depends on an amount of a spherical aberration of an exposure projection lens.

In other words, the pattern forming method of the present invention uses a phase-shift mask, especially a positive type Levenson phase-shift mask and moving a substrate or the phase-shift mask along an optical axis to thereby expose a pattern onto a plurality of image-forming surfaces. By this-method, it is possible to greatly reduce a dimensional fluctuation due to a defocus and a lens aberration, which causes a trouble when a phase-shift mask is used.

### BRIEF DESCRIPTION OF THE DRAWINGS

FIGS. 1 are plan views for showing masks used in one embodiment of the pattern forming method according to a present invention, of which FIG. 1[1] shows a phase-shift mask used in a first exposure, FIG. 1[2] shows an ordinary mask used in a second exposure, and FIG. 1[3] shows a circuit pattern formed by these exposure steps;

FIG. 2 is a configuration diagram for showing an exposure apparatus used in the embodiment of present invention;

FIG. 3 is an illustration for showing exposure operations according to the embodiment of the present invention;

FIG. 4 are graphs for showing a light-intensity distribution of positions on a wafer according to the embodiment of the present invention, of which FIG. 4[1] indicates a light-intensity for each focus and FIG. 4[2] indicates that as averaged by multiple-focus exposure;

FIG. 5 is a graph for showing a CD-focus characteristic of phase-shifted exposure by the embodiment of the present invention and that by prior art phase-shifted exposure;

FIG. 6 is a graph for showing a CD-focus characteristic in a case where a horizontal axis of the graph of the prior art phase-shifted exposure is extended;

FIG. 7 is a graph for showing a CD-focus characteristic of phase-shifted exposure by the embodiment of the present invention and that by the prior art phase-shifted exposure in a case where a spherical aberration is present;

FIG. 8 is a graph for showing an optical contrast of a 100-nm-wide isolated line in cases of KrF-Excimer laser exposure (wavelength: 248 nm) and ArF-Excimer later exposure (wavelength: 193 nm);

FIG. 9 is a graph for showing a CD-focus characteristic of the prior art phase-shifted exposure; and

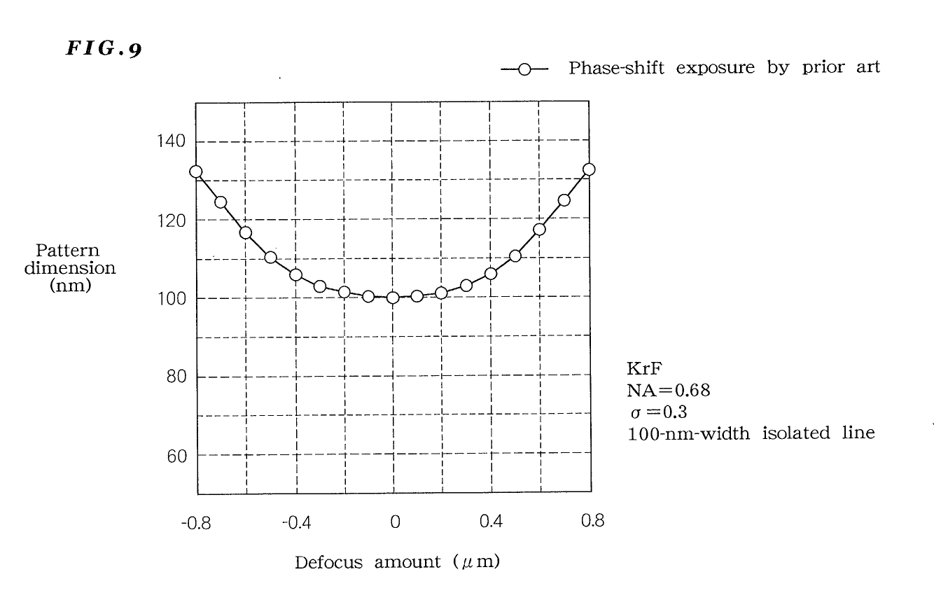

FIG. 10 is a graph for showing a CD-focus characteristic of the prior art phase-shifted exposure in a case where a spherical aberration is present.

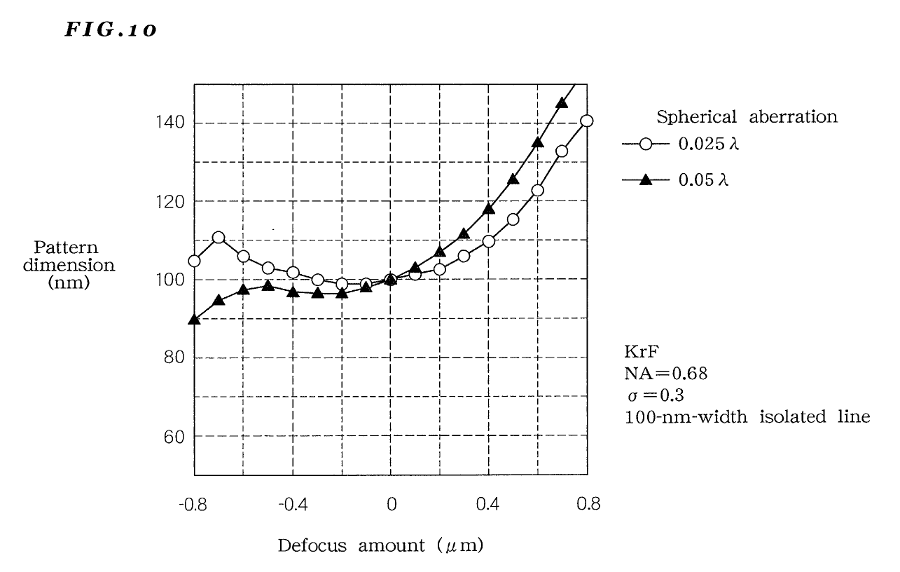

### DESCRIPTION OF THE PREFERRED EMBODIMENTS

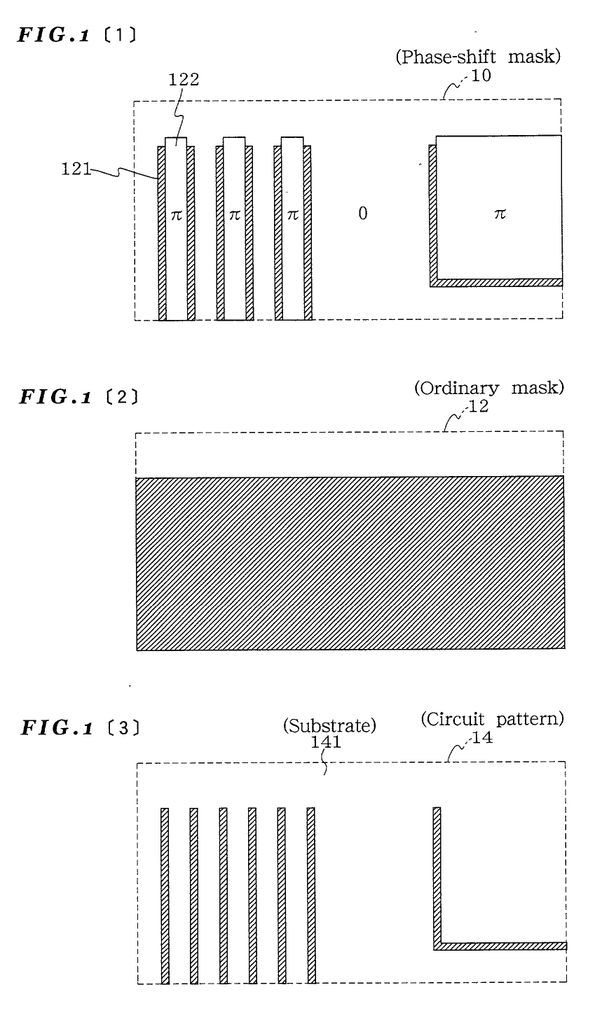

FIG. 1 are plan views for showing a mask etc. used in one embodiment of the pattern forming method according to the present invention, of which FIG. 1[1] shows a phase-shift mask used in a first exposure, FIG. 1[2] shows an ordinary mask used in a second exposure, and FIG. 1[3] shows a circuit pattern formed by these exposure steps. The following will describe the embodiment with reference to these figures.

As a phase-shift mask 10, a positive type Levenson phase-shift mask is used. The Levenson phase-shift mask is extremely effective in improvement of a resolution and a depth of focus and capable of resolving an ultra-fine pattern of an exposure light wavelength or less. The following will describe a case, for example, where a device with a minimum line width of 100 nm such as that of a gate-layer circuit pattern 14 is exposed by a projection exposure apparatus using a KrF-Excimer laser as its light source. In this embodiment, the circuit pattern 14 is formed by performing exposure twice using the phase-shift mask 10 and an ordinary mask 12 respectively. In the first exposure using the phase-shift mask 10, a substrate 141 is moved along an optical axis to thereby expose the pattern onto a plurality of image-forming surfaces.

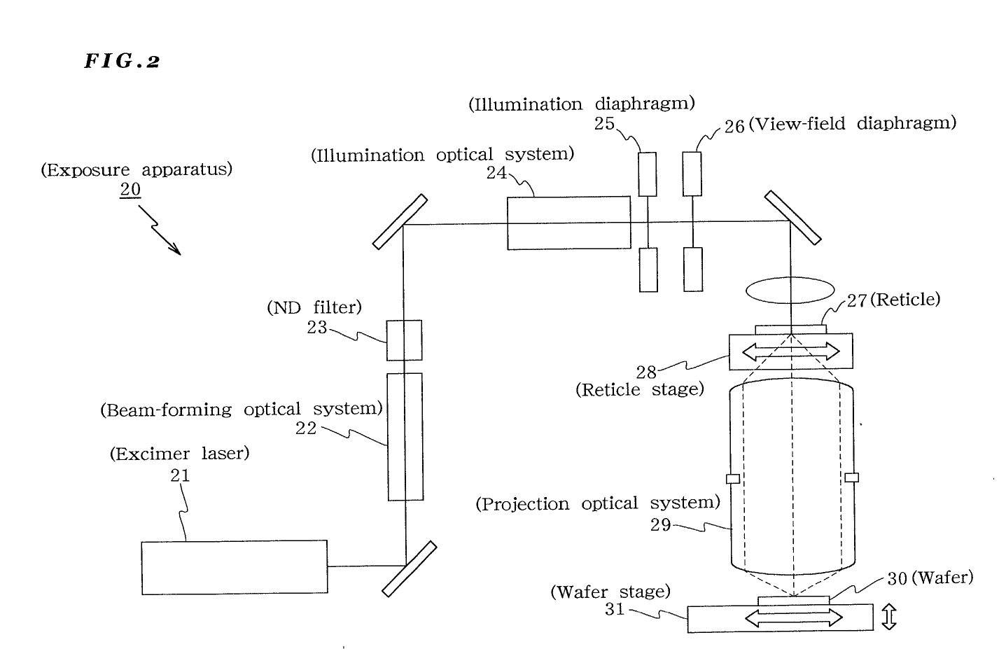

FIG. 2 is a configuration diagram for showing an exposure, apparatus used in the embodiment of present invention. The following will describe the embodiment with reference to this figure.

An exposure apparatus 20 is of a step-and-scan exposure type using a KrF-Excimer laser as its light source and specifically includes an Excimer laser 21, a beam forming optical system 22, an ND filter 23, an illumination optical system 24, an illumination diaphragm 25, a view-field diaphragm 26, a reticle 27 (mask), a reticle stage 28, a projection optical system 29, a wafer 30 (substrate), and a wafer stage 31. A KrF-Excimer laser beam emitted from the Excimer laser 21 passes through the beam forming optical system 22, the illumination optical system 24, the view- field diaphragm 26, etc. to be shaped into a slit-shaped illumination flux and then applied onto the reticle 27. The reticle 27 and the wafer 30 are scanned, under the illumination, in synchronization with each other at a speed which corresponds to a reduction ratio, thus transferring a pattern onto the wafer 30. In this step, the numerical aperture (NA) of the projection optical system 29 is 0.68 and the coherence factor (σ) of the illumination optical system 24 is 0.3. Also, the wafer stage 31 is equipped with an optical-axial direction moving mechanism made of a piezo-electric element etc. for adjusting the height in an optical axial direction (Z-direction).

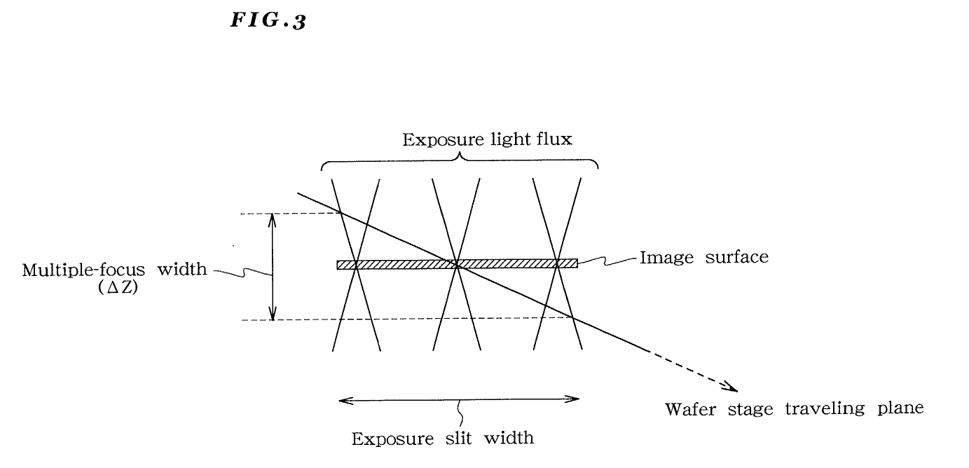

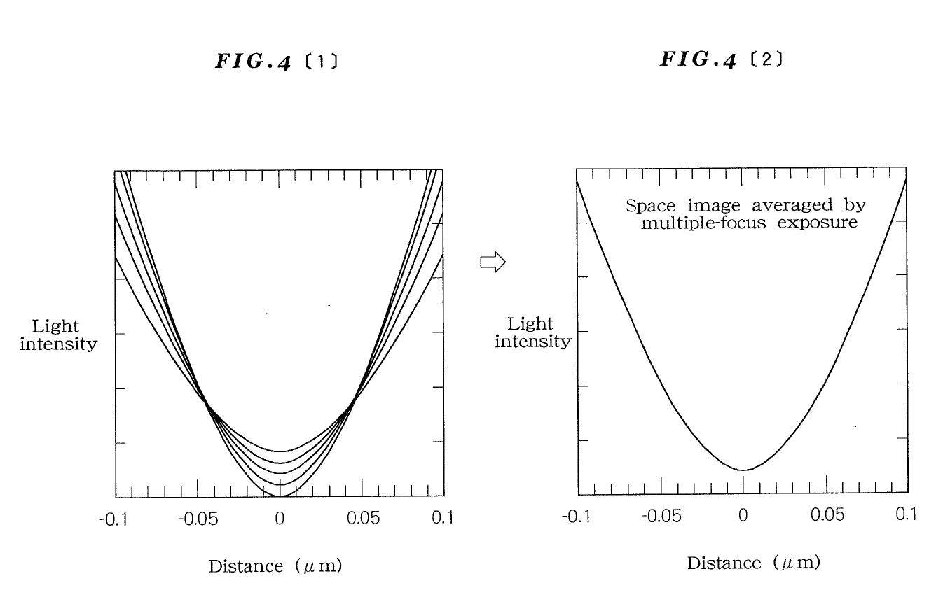

FIG. 3 is an illustration for showing exposure operations according to the embodiment of the present invention. FIGS. 4 are graphs for showing a light-intensity distribution of various positions on the wafer 30 according to the embodiment of the present invention, of which FIG. 4[1] indicates a light-intensity for each focus and FIG . 4[2 ] indicates that as averaged by multiple-focus exposure. The following will describe the embodiment according to FIGS. 1-4.

In the first exposure, the phase-shift mask 10 of FIG . 1[1] is used. In the phase-shift mask 10, light-blocking portion 121 is provided with a phase shifter 122 so that exposure lights passing through the right and left sides respectively of the light-blocking portion 121 may differ in phase by 180° from each other. With this, the photoelectric fields of these two exposure lights around a boundary therebetween are offset (counteracted) each other completely to thereby form an extremely sharp dark space, thus enabling forming an ultra-fine pattern.

This first exposure is performed in a multiple-focus manner. By the multiple-focus exposure, the optical-axial-directional (Z-directional) height of the wafer stage 31 is changed during exposure. In the case of the exposure apparatus 20 of FIG. 2, the height of the wafer stage 31 is variably changed. As shown in FIG. 3, by continuously inclining a traveling plane of the wafer stage 31 with respect to an image surface, a defocus amount is variably changed within an exposure slit.

By this embodiment, a multiple-focus width ΔZ (movement of Z-direction) is set at 1 μm, for example. In this case, if a defocus amount it +0.5 μm at a start point of scan exposure, the defocus amount gradually changes negative as scan proceeds, coming down to −0.5 μm at an end point of the scan exposure. As shown in FIGS. 4, such a space image is formed finally that is obtained by averaging the space images which change with a changing defocus amount of from +0.5 μm to −0.5 μm.

As a result of the first exposure, other than the desired circuit pattern 14, a dark portion is generated at the edge of the phase shifter 122. To prevent this undersired dark portion from being resolved into a resist pattern, the second exposure is performed. Using the ordinary mask 12 of FIG . 1[2] to shut out the light from all the 100-nm-wide line areas formed by the first phase-shifted exposure and thereby expose the other areas, the undesired dark portion is eliminated. Subsequently, development is performed to thereby obtain the circuit pattern 14 of FIG. 1[3].

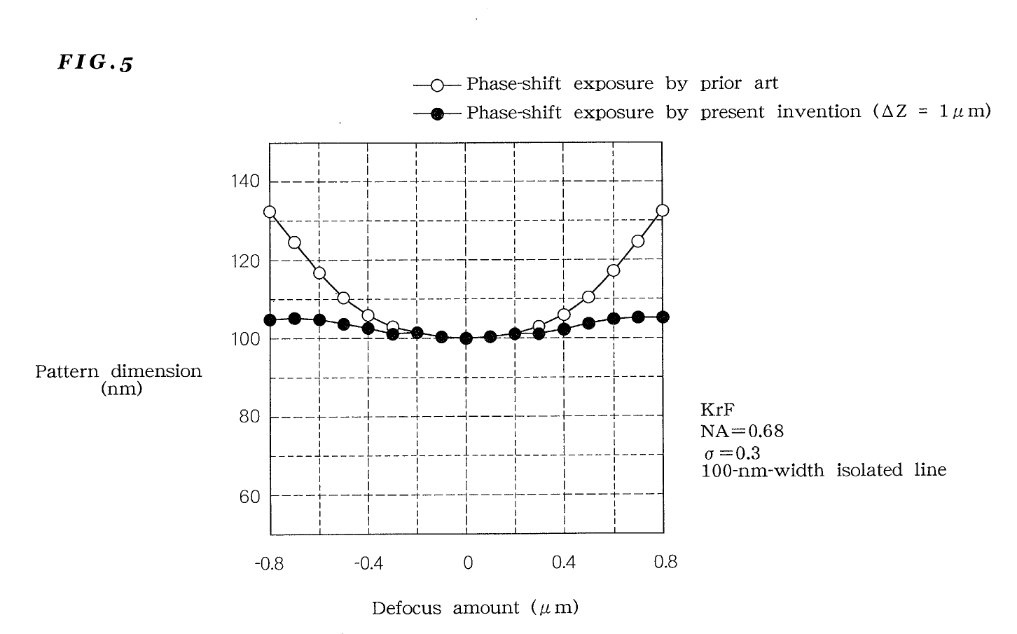

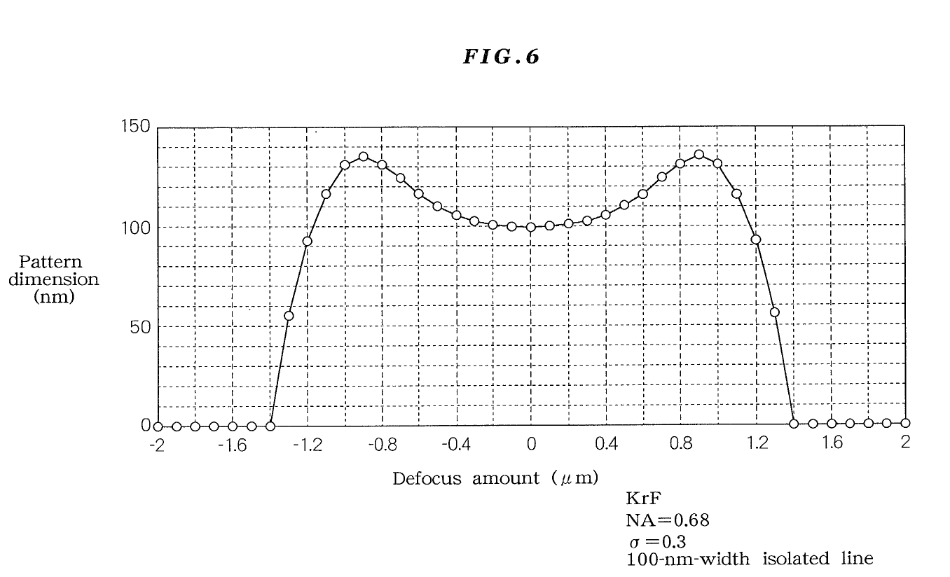

FIGS. 5 and 6 are graphs for showing a CD-focus characteristic (a relationship between a defocus amount and a pattern dimension) in a case where no lens aberration is present, of which FIG. 5 provides a comparison between phase-shift exposure by the embodiment of the present invention and that by prior art phase-shift exposure and FIG. 6 is a graph for showing a CD-focus characteristic in a case where a horizontal axis of the graph of the prior art phase-shifted exposure is extended. The following will describe the embodiment with reference to these figures.

In those figures, “defocus amount” in this embodiment represents an average (intermediate value) of multiple-focus widths. For example, a defocus amount of 0 μm is an average of multiple-focus exposure defocus amounts of +0.5 μm to −0.5 μm and a defocus amount of +0.5 μm is an average of multiple-focus exposure defocus amounts of +1.0 μm to 0 μm.

As mentioned above, this embodiment has an NA value of 0.68 of the projection optical system, a 0 value of 0.3 of the illumination optical system, and a multiple-focus width (ΔZ) of 1 μm. If there is no lens aberration present, there is no asymmetry of the focus. By the prior art, however, even with no aberration, a defocus amount, if large, causes a pattern dimension to rapidly expand problematically. In contrast to the prior art, by this embodiment, defocusing causes rather a small fluctuation in dimension, thus enabling increasing the depth of focus and improving the dimensional accuracy.

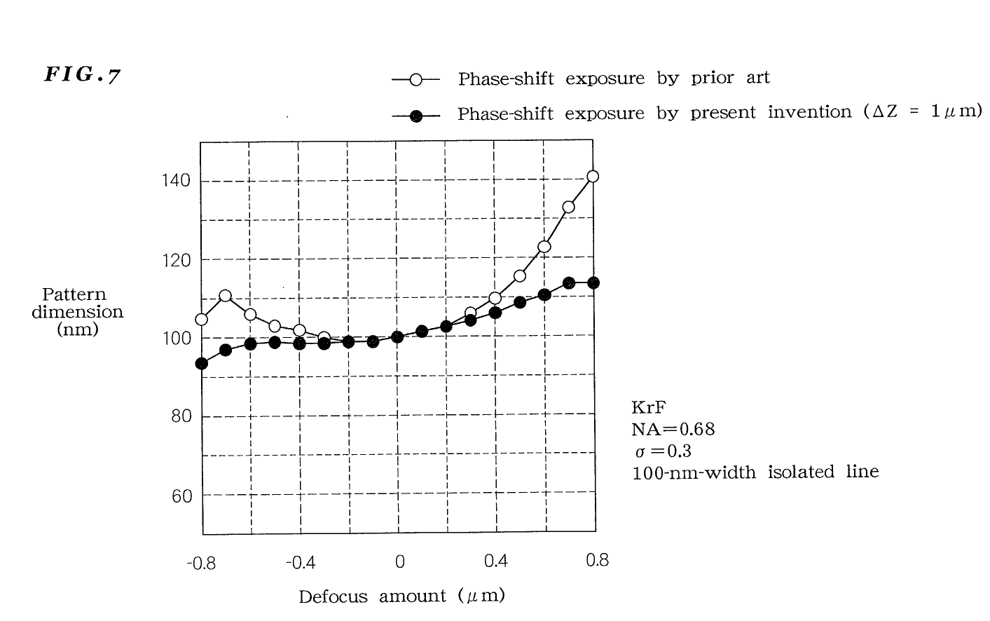

FIG. 7 is a graph for showing a CD-focus characteristic of phase-shift exposure by this embodiment of the present invention and that by the prior art phase-shift exposure in a case where a spherical aberration of 0.025λ is present. The following will describe the embodiment with reference to FIG. 7.

Phase-shift exposure is liable to be influenced by a spherical aberration; in fact, by the prior-art, there is observed remarkable asymmetry between plus defocus and minus defocus. In contrast to the prior art, this embodiment can greatly eliminate the asymmetry by an effect of space image averaging, thus significantly improving the dimensional accuracy. In this case, a constant distance by which either the phase-shift mask or the substrate is moved along the optical axis is determined taking asymmetry considering that an average of errors in the pattern dimensions may be 0.

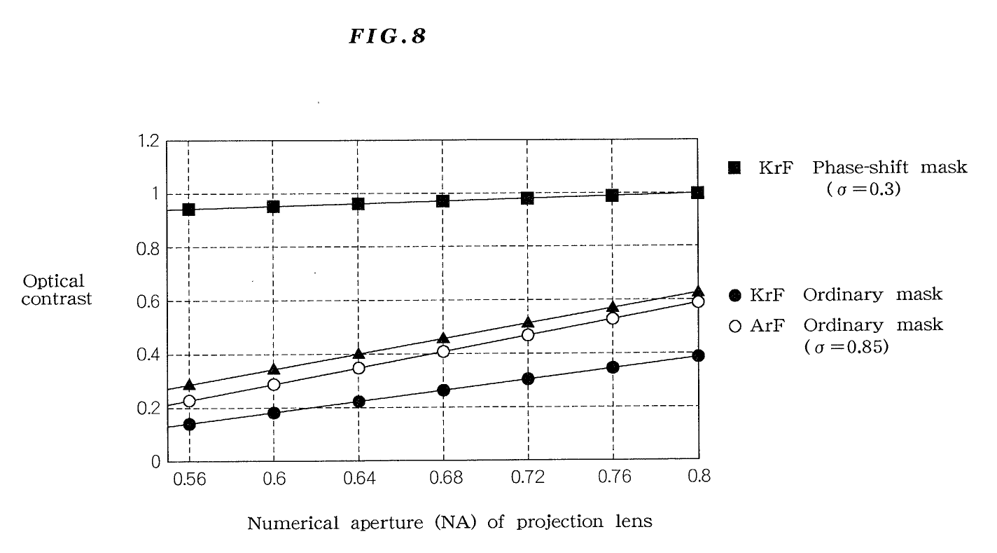

Next, this embodiment is summarized. It is commonly considered that the multiple-focus exposure method suffers from deterioration in optical contrast as compared to a typical exposure method and therefore is not capable of forming an ultra-fine pattern, especially a positive pattern. This embodiment, however, employs a Levenson phase-shift mask (see FIG. 8) having a very high optical contrast and so is capable of keeping such a high contrast as to enable sufficient resolving even if a multiple-focus width is set at a large value of 20 μm or more.

It should be noted that although this embodiment has exemplified a scan exposure apparatus, a one shot exposure apparatus (stepper) may be used. By the one shot exposure apparatus, it is possible to variably change the height of the stage within an exposure time like by the scan exposure apparatus as well as to perform exposure a plurality of times while changing the stage height for each time of exposure, thus changing a defocus amount discretely.

Also, although this embodiment has been described with reference to a case where the wafer stage height, i.e. substrate height is changed, the height of the mask stage may be changed taking a projection ratio into account, to obtain almost the same effects.

Further, although this embodiment has exemplified use of, especially a positive type Levenson phase-shift mask, the invention may be applied also to a half-tone phase-shift mask, a rim-type half-tone phase-shift mask, etc. to obtain almost the same effects. Note here that a rim-type half-tone phase-shift mask refers to such a mask that only the vicinity of an edge of an opening may be half-toned.

By the pattern forming method related to the invention, a pattern can be exposed while moving at least one of the phase-shift mask and the substrate by a constant distance along an optical axis, to average an error in pattern dimensions caused by a defocus or a spherical aberration, thus improving the dimensional accuracy.

Especially when a positive type Levenson phase-shift mask is used as the phase-shift mask, it is possible to obtain an extremely high optical contrast and thereby compensate for a decrease in optical contrast, which is a disadvantage of multiple-focus exposure, thus keeping such a high contrast as to enable sufficient resolving even if the multiple-focus width is set at a large value of 2 μm.

Also, by determining the constant distance by which at least one of the phase-shift mask and the substrate is to be moved along the optical axis corresponding to an amount of a spherical aberration of the exposure projecting lens, it is possible to largely eliminate a disadvantage of the phase-shifted exposure method of being liable to be influenced by the spherical aberration by the space-image averaging effect, thus greatly improving the dimensional accuracy.

The invention may be embodied in other specific forms without departing from the spirit or essential characteristic thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2000-351164 (Filed on Nov. 17, 2000) including specification, claims, drawings and summary are incorporated herein by reference in its entirety.

What is claimed is:

1. A pattern forming method for forming a predetermined pattern onto a resist film on a substrate by exposing said predetermined pattern through a phase-shift mask while moving at least one of said phase-shift mask and said substrate by a constant distance along an optical axis.

2. The pattern forming method according to claim 1, wherein said phase-shift mask is a positive type Levenson phase-shift mask.

3. The pattern forming method according to claim 1, wherein said pattern is a line pattern.

4. The pattern forming method according to claim 2, wherein said pattern is a line pattern.

5. The pattern forming method according to claim 3, wherein a lower dimensional limit of said line pattern is not more than about a half of a wavelength of an exposure light.

6. The pattern forming method according to claim 4, wherein a lower dimensional limit of said line pattern is not more than about a half of a wavelength of an exposure light.

7. The pattern forming method according to claim 1, wherein a coherence factor of an exposure illumination optical system is not more than 0.5.

8. The pattern forming method according to claim 2, wherein a coherence factor of an exposure illumination optical system is not more than 0.5.

9. The pattern forming method according to claim 1, wherein said constant distance is determined corresponding to a spherical aberration of an exposure projection lens.

10. The pattern forming method according to claim 2, wherein said constant distance is determined corresponding to a spherical aberration of an exposure projection lens.

11. The pattern forming method according to claim 1, wherein said constant distance is 1 μm.

12. The pattern forming method according to claim 2, wherein said constant distance is 1 μm.

13. The pattern forming method according to claim 1, wherein a light source used in the pattern forming method is KrF-Excimer laser or ArF Excimer laser.

14. The pattern forming method according to claim 2, wherein a light source used in the pattern forming method is KrF-Excimer laser or ArF Excimer laser.
